(19) United States
(12) Patent Application Publication
(10) Pub. No.: US 2017/0113296 A1
(43) Pub. Date: Apr. 27, 2017

(54) BOND HEAD ASSEMBLY AND SYSTEM

(71) Applicant: Duetto Integrated Systems, Inc., Islandia, NY (US)

(72) Inventors: ANTHONY FARACI, Commack, NY (US); Gary N. Sortino, Baldwin, NY (US)

(73) Assignee: Duetto Integrated Systems, Inc., Islandia, NY (US)

(21) Appl. No.: 15/390,274

(22) Filed: Dec. 23, 2016

Related U.S. Application Data
(63) Continuation of application No. 12/377,268, filed on Mar. 24, 2010, now abandoned.
(60) Provisional application No. 60/824,263, filed on Aug. 31, 2006.

(51) Int. Cl. B23K 13/01; H05B 6/06; H05K 1/11; H05B 6/40; H05K 3/46; H05K 1/09

(52) U.S. Cl. CPC B23K 13/01; H05K 3/4611; H05K 1/09; H05K 1/11; H05B 6/40; H05B 6/06; H05K 2203/11; B23K 2201/42

(57) ABSTRACT

An inductive thermal bonding system includes at least one inductive bonding or heating member containing a magnetic E-shaped inductive core and a coil bounding a central member of the E-shaped inductive core. A rigid cover plate allows high and predictable temperature rate-of-change during use and reduced thermal cycling time without risk of detriment. Adaptive solid copper pads on multiplayer bonding regions minimize bonding errors and improve reliability. A cooling system is provided for adaptively cooling both the bond head and the bonded stack. Single and paired inductive heating members may be employed, and may also be alternatively controlled and positioned to aid generation of multiplayer bonding subassemblies distant from an edge of a multiplayer sheet construct.

### CROSS REFERENCE TO RELATED APPLICATIONS

This application claims priority from and is a continuation of U.S. Ser. No. 12/377,268 filed Mar. 24, 2010, the entire contents of which are incorporated by reference; which in turn claims §371 priority from PCT/US2007/77178 filed Aug. 30, 2007 which in turn claims priority from U.S. Provisional Patent Application Ser. No. 60/824,263 filed Aug. 31, 2006, the entire contents of which are herein incorporated by reference.

### BACKGROUND OF THE INVENTION

1. Field of the Invention

The present invention relates to an inductive bond head assembly, construction, and system for operating the same within a multiplayer bonding process. More specifically, the present invention relates to a bond head assembly containing separately operable bonding heads usable without connective circuitry.

2. Description of the Related Art

The related art involves U.S. Pat. No. 7,009,157 to Gallego, the entire contents of which are herein incorporated by reference. The Gallego '157 patent involves a procedure for soldering layers of a multiplayer printed circuit and a machine for the same.

As noted in the '157 disclosure, edges of multiplayer printed circuit pre-forms require inductive bonding and rigid C or U-shaped inductive head assemblies are used employing a combination of (a) single U-shaped magnetic circuit inductive bonding device with two inductive electrical members extending from each C- or U-shaped ferrite core member and (b) a heating circuit composed of a flat winding with at least one turn in short circuit in a bonding area of each layer.

In use, individual sides of U- or C-shaped magnetic inductive bonding devices are positioned in contact with the outermost flat windings of a respective multiplayer circuit arrangement and electrical power is applied. As discussed in the reference, each inductive bonding device includes a single coil with arms of the core extending outwardly in a U- or C-shape. The individual sheets are then retained between the extending arm parts and both arms are induced jointly as required by the construction.

The electrical power induces a magnetic field in each side (each leg) of the inductive device simultaneously which in-turn induces heating in the short circuit winding in each layer's heating circuit. In such combination, heat is induced in each heating circuit between the arms of each leg, and with an adhesive inter-sheet between layers, is used to bond respective multiplayer circuit arrangements.

Unfortunately, the Gallego '157 system provides substantial manufacturing disadvantages and limitations which have not been overcome in the related art and for which technical appreciation is lacking. These limitations and disadvantages include, but are not limited to:
(a) A requirement for a U- or C-shaped inductive bonding core mechanism which in-turn fixes induction within the extending bonding arms of both sides in coaxial positions with one another, thereby allowing only axial repositioning depending upon a multiplayer thickness and preventing respective lateral displacement between arms for use as single-side bonding heads and prevents use in mid-layer and mid-sheet sub-assembly positioning (the C- or U-shape cannot be broken without inductive failure) resulting in a loss of manufacturing efficiency.
(b) A requirement for a defined reserve region on each sheet to include a flat copper winding with at least one turn in short-circuit so that upon use the induced current in the short-circuit raises temperature. Unfortunately, this requires (a) costly and time consuming intricate circuitry winding construction within each short circuit, (b) a risk of mis-alignment of such short circuits and such particular windings, (c) and slowed heat-up induction time due to the non-copper coated portions between each ring of the winding and of each short-circuit preventing direct conductive thermal transfer.
(c) A requirement for a control system that operates both inductive sides of the U- or C-shaped inductive bonding mechanism in tandem from a single core; thereby preventing a control system adaptive to vary an induction on a respective induction coil to tailor a heat-up cycle for layer thickness, to compensate for mis-positioning, to prevent the use of such a system to generate custom induction routines, and requiring extensively long induction/heating cycles.

Ultimately, what is not appreciated by the related art is the need for an inductive bonding head system responsive to the concerns noted above. Accordingly, there is a need for an improved bonding head assembly and system, as well as an optional need for an improved unified bonding system that employs such an improved bonding head assembly and system.

Accordingly, there is a need for an improved bond head assembly and system as will be discussed.

### OBJECTS AND SUMMARY OF THE INVENTION

A goal of the present invention is to provide an improved bonding head assembly responsive to at least one of the needs noted above.

The present invention relates to an inductive thermal bonding system includes at least one inductive bonding or heating member containing a magnetic E-shaped inductive core and a coil bounding a central member of the E-shaped inductive core. A rigid cover plate allows high and predictable temperature rate-of-change during use and reduced thermal cycling time without risk of detriment. Adaptive solid copper pads on multiplayer bonding regions minimize bonding errors and improve reliability. A cooling system is provided for adaptively cooling both the bond head and the bonded stack. Single and paired inductive heating members may be employed, and may also be alternatively controlled and positioned to aid generation of multiplayer bonding subassemblies distant from an edge of a multiplayer sheet construct.

According to an embodiment of the present invention there is provided an inductive bonding system, comprising: at least a first inductive bonding head member, further comprising: at least a first E-shaped core member having a central leg and two outer side legs joined with a continuous back member, at least a first coil assembly bounding a central portion of the core member, at least a containment member for bounding the core member and the coil assembly, at least one non-stick cover member for providing an inductive work surface for contacting an inductive work position, the non-stick cover member being at least one of a ceramic material, a metallic material, and a polymeric material, and control means for mechanically positioning and electrically controlling the at least first (at least one) E-core member relative to the inductive work position.

According to another aspect of the present invention there is provided an inductive bonding system, further comprising: thermocouple means for positioning a means for reading a temperature proximate a position between one leg of the core member and the coil assembly.

According to another aspect of the present invention, there is provided an inductive bonding system, further comprising: thermocouple means for reading a temperature proximate a center leg of the E-shaped core involving a thin-film (thin layer) thermocouple either bonded to a cover plate or separate from the cover plate.

According to another aspect of the present invention there is provided an inductive bonding system, further comprising: cooling means for providing a jet cooling of the at least one bonding head, whereby the cooling means enables a thermal management of the bonding system and reduced bonding-time cycles.

According to another aspect of the present invention, there is provided an inductive bonding system, comprising: a multiplayer circuit construction including inductive bonding work regions on each circuit layer, and each the inductive bonding work region being at least one of a continuous metallic region, a discontinuous metallic region, an assembly of concentric ring members bounding a central core, a centrally located oval pad member, a centrally located round pad member, and a centrally located rectilinear member.

According to an embodiment of the present invention there is provided an inductive bonding system, comprising: at least one inductive bonding head member, the inductive head member further comprising: an E-shaped ferrite core member having a central leg and two outer legs joined by a back member, at least a first coil member bounding the central leg and having a plurality of coil turns, a cover plate member on a contact surface of at least the central leg of the E-shaped ferrite core member and having a bonding surface opposite the contact surface during a use of the bonding system, at least one rigid core block means for bounding the E-shaped ferrite core member and the first coil member, and for supporting the cover plate member, and a temperature measurement means between the cover plate member and the E-shaped ferrite core member, whereby the ferrite core member and the coil member generate an inductive field during the use that is substantially split between the central leg and the two outer legs enabling a concentration of the field proximate the central leg for improved inductive bonding.

According to another optional embodiment of the present invention there is provided an inductive bonding system, wherein: the cover plate member includes a material selected from a material group comprising: of at least one of a ceramic material, a metallic material, a polymeric material, and a combination of two of the ceramic, metallic, and the polymeric materials.

According to another optional embodiment of the present invention there is provided an inductive bonding system, further comprising: control means for positioning and electrically controlling the inductive bonding head member relative to an inductive work position, whereby during the use the control means for positioning enables the inductive bonding head member to approach and retract from the work position.

According to another optional embodiment of the present invention there is provided an inductive bonding system, further comprising: cooling means for providing a cooling management of one of the inductive bonding head member during the use and an external bonded material during the use, wherein the cooling means enables a reduced bonding cycle time.

According to another optional embodiment of the present invention there is provided an inductive bonding system, further comprising: control means for aligning and positioning the inductive bonding head member relative to the inductive bonding at a work position during the use.

According to another optional embodiment of the present invention there is provided an inductive bonding system, wherein: the plurality of coil turns in the at least first coil member is between 30 and 56 turns.

According to another optional embodiment of the present invention there is provided an inductive bonding system, wherein: the plurality of coil turns in the at least first coil member is between 30 and 40 turns.

According to another optional embodiment of the present invention there is provided an inductive bonding system, further comprising: at least a second inductive bonding head member, the second inductive bonding head member further comprising: a second E-shaped ferrite core member having a central leg and two outer legs joined by a back member, a second coil member, a second cover plate member on the central leg of the second E-shaped ferrite core member, a second rigid core block means for bounding the second E-shaped ferrite core member and the second coil member, and for supporting the second cover plate member, and a second temperature measurement means between the second cover plate member and the second E-shaped ferrite core member.

According to another optional embodiment of the present invention there is provided an inductive bonding system, comprising: at least one inductive bonding head member, the inductive head member further comprising: an E-shaped ferrite core member having a central leg and two outer legs joined by a back member, a coil member bounding the central leg and having a plurality of coil turns, a cover plate member on the E-shaped ferrite core member and having a bonding surface opposite the E-shaped ferrite core member during a use of the bonding system, a core block means for bounding the E-shaped ferrite core member and the first coil member, and for supporting the cover plate member during the use, and a temperature measurement means between the cover plate member and the E-shaped ferrite core member, whereby the ferrite core member and the coil member generate an inductive field during the use that is substantially split between the central leg and the two outer legs enabling a concentration of the field proximate the central leg for improved inductive bonding.

According to another optional embodiment of the present invention there is provided an inductive bonding system, further comprising: adjustment means for positioning and for securing the inductive bonding head member relative to a desired inductive work position throughout a field of possible work positions, whereby during the use the adjustment means for positioning and for securing enables the inductive bonding head member to repositionably approach a work position for bonding and to be re-locatably secured with a field of possible work positions for enhanced bonding efficiency.

According to another optional embodiment of the present invention there is provided an inductive bonding system, further comprising: cooling means for providing a cooling management of one of the inductive bonding head member during the use and an external bonded material bonded during the use, wherein the cooling means enables a reduced thermal cycle time.

According to another optional embodiment of the present invention there is provided an inductive bonding system, further comprising: computer controlled means for repositionably aligning and operating the inductive bonding head member relative to a desired inductive work position throughout a field of possible work positions during the use.

According to another optional embodiment of the present invention there is provided an inductive bonding system, comprising: at least a first inductive bonding head member, at least a first multi-layer circuit construction stack comprising at least one layer of bonding resin between two printed circuit layers, each the printed circuit layer including an inductive bonding work region positionable relative to the bonding head member, and each the inductive bonding work region comprising:one of a continuous metallic region, a discontinuous metallic region, an assembly of a ring member bounding a centrally located continuous metallic region, whereby during a bonding the inductive bonding head member induces a thermal field relative to the entire bonding work region, liquefies the proximate bonding resin, and bonds the respective printed circuit layers.

According to another optional embodiment of the present invention there is provided an inductive bonding system, wherein: the inductive bonding work region includes the continuous metallic region, and the continuous metallic region is a Copper (Cu) metallic region.

According to another optional embodiment of the present invention there is provided an inductive bonding system, wherein: the continuous metallic region is bounded by a ring member, and the ring member is constructed from one of a Copper (Cu) ring and an etched region in the printed circuit layer.

According to another optional embodiment of the present invention there is provided a printed circuit layer, comprising: at least one printed circuit layer sheet having an inductive bonding work region defined within the edges thereof, and each the inductive bonding work region comprising: one of a continuous metallic region, a discontinuous metallic region, an assembly of a ring member bounding a centrally located continuous metallic region, whereby during a bonding the inductive bonding head member induces a thermal field relative to the entire bonding work region, liquefies the proximate bonding resin, and bonds the respective printed circuit layers.

According to another optional embodiment of the present invention there is provided an adjustable inductive bonding system, wherein: at least first and second inductive bonding head members, each the inductive head member further comprising: an E-shaped ferrite core member having a central leg and two outer legs joined by a back member, a coil member bounding the central leg and having a plurality of coil turns, a cover plate member on the E-shaped ferrite core member and having a bonding surface opposite the E-shaped ferrite core member during a use of the bonding system, a core block means for bounding the E-shaped ferrite core member and the first coil member, and for supporting the cover plate member during the use, a temperature measurement means between the cover plate member and the E-shaped ferrite core member, whereby the ferrite core member and the coil member generate an inductive field during the use that is substantially split between the central leg and the two outer legs enabling a concentration of the field proximate the central leg for improved inductive bonding, means for independently positioning the first and the second bonding head members and for repositionably moving the first and second bonding head members toward each other during the use, cooling means on at least one of the inductive bonding head members for providing a cooling management of at least one of the one inductive bonding head member during and an external bonded material bonded during the use, wherein the cooling means enables a reduced thermal cycle time of the inductive bonding system.

According to another optional embodiment of the present invention there is provided an adjustable inductive bonding system, wherein: the means for independently positioning and for repositionably moving further comprises: means for securely positioning the first and second inductive bonding head members at a desired inductive work position throughout a field of possible work positions in the system, the means for securely positioning, comprising: at least a first support bar member, at least one of the inductive bonding head members on the support bar member, a means for sliding ones of the inductive bonding head members relative to the at least first support bar member to a desired the inductive work position, whereby the means for sliding enables easy repositioning of the ones of the inductive bonding head members.

According to another optional embodiment of the present invention there is provided an adjustable inductive bonding system, wherein: the means for securely positioning, further comprises: at least a second support bar member, one of the inductive bonding head members on the first support bar member and the other of the inductive bonding head members on the second support bar member, the means for sliding enabling independent positioning of each the first and second inductive bonding head members independent from the other for enhanced ease of use.

According to another optional embodiment of the present invention there is provided an adjustable inductive bonding system, wherein: sliding means for slidably moving respective first and second support bar members securing respective first and second inductive bonding head members relative to the field of possible work positions in the system, whereby the means for independently positioning and for repositionably moving enables each the bonding head member to traverse the entire field of possible work positions in at least three directions.

The above, and other objects, features and advantages of the present invention will become apparent from the following description read in conduction with the accompanying drawings, in which like reference numerals designate the same elements.

### BRIEF DESCRIPTION OF THE DRAWINGS

FIG. 1 is a perspective view of an adjustable bond head assembly and system employing separable bonding head members.

FIG. 2 is a side perspective view of an adjustable bond head assembly arranged with a layered stack during an assembly step.

FIGS. 2A through 2D are planar elevational views of alternative bonding pad configurations.

FIG. 3 is a perspective exploded view of an individual bond head assembly.

FIG. 4 is a partially cut-away top view of an assembled bond head assembly.

FIG. 5 is a sectional view along line 5-5 in FIG. 4 depicting assembled bond head construction.

FIG. 6 is a side elevational view of mobile top and bottom bond head assemblies positioned relative to a support plate and a sheet or stack of sheets prior to a bonding step.

FIG. 7 is a side elevational view of mobile top and bottom bond head assemblies positioned close to a just-bonded stack of sheets noting the direction of sheet and bond head cooling offered by the presently proposed cooling systems.

FIG. 8 is a perspective pictorial view of a unified bonding system containing a loading station, an alignment station, and multiple bonding stations for enhanced efficiency.

FIG. 9 is a graph depicting the coil turns to heat rate effect over time for differing coil turn numbers between top and bottom bond head assemblies.

### DETAILED DESCRIPTION OF THE PREFERRED EMBODIMENTS

Reference will now be made in detail to several embodiments of the invention that are illustrated in the accompanying drawings. Wherever possible, same or similar reference numerals are used in the drawings and the description to refer to the same or like parts or steps. The drawings are in simplified form and are not to precise scale. For purposes of convenience and clarity only, directional terms, such as top, bottom, up, down, over, above, and below may be used with respect to the drawings. These and similar directional terms should not be construed to limit the scope of the invention in any manner. The words “connect,” “couple,” and similar terms with their inflectional morphemes do not necessarily denote direct and immediate connections, but also include connections through mediate elements or devices.

As employed herein the phrases bonding head, bonding member, induction head, induction core, and core may be adaptively employed depending upon the descriptive environment without departing from the scope and spirit of the present invention and within the understanding of those of skill in the art having considered the entire disclosure.

According to the present discussion, a system has been developed to bond different layers and sub-assemblies together with mid-field sheet bonding ability and single-sheet side bonding ability. The bond system can be configured with a single bond head or two opposing bond heads and may be readily automated and configured for different sheet sizes and dimensions and for movement in three directions (X, Y, and Z).

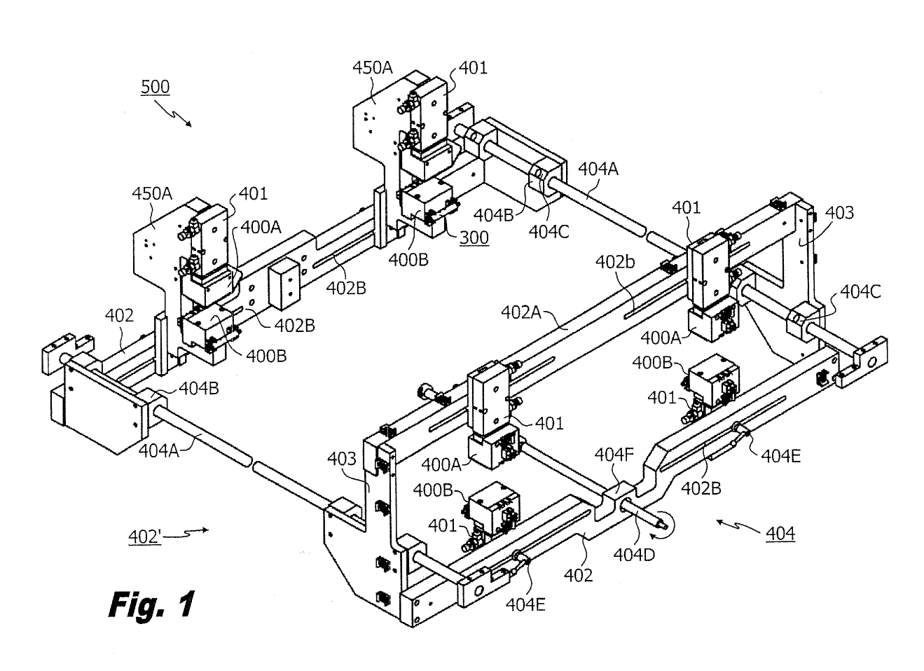

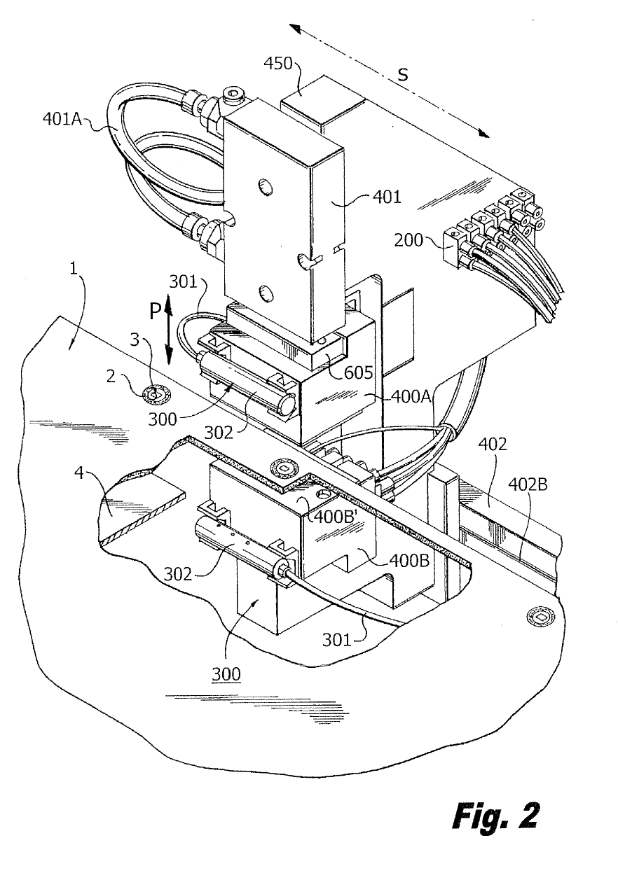

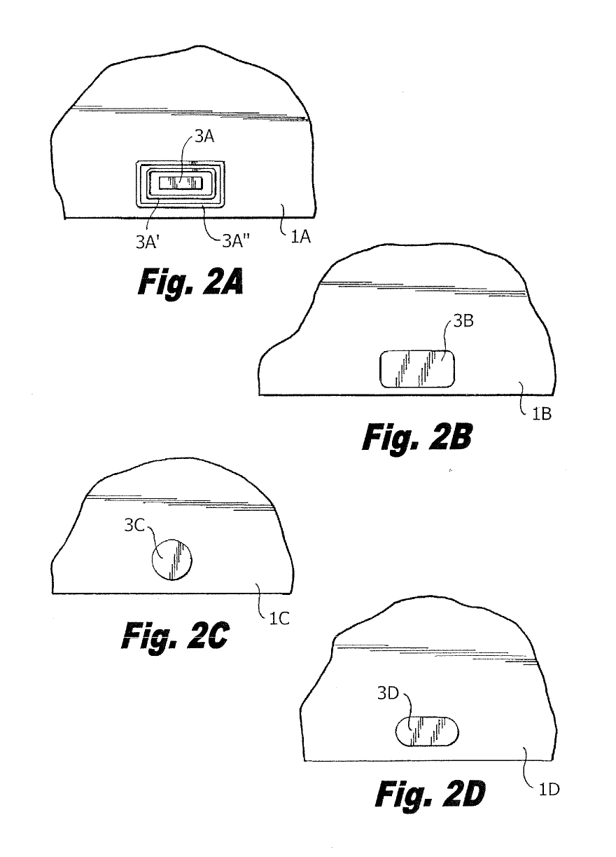

Referring now to FIG. 1 through FIG. 2D, an integrated bonding station assembly 500 is proposed and includes a plurality of bond head assemblies 400 depicted respectively as top and bottom bond head assemblies 400A, 400B. A support frame assembly 402′ includes a plurality of horizontal support bars 402, 402 joined by an adjustable positioning system 404 including respective sliding shaft members 404A, 404A with sliding bearing blocks 404B and locking pins 404C in blocks 404B for fixing a final adjusted position during a set-up or an assembly depending upon a manufacturer's requirements. A top horizontal support bar 402A extends from vertical support members 403, 403 fixed to respective ends of one of the horizontal support bars 402, as shown. A plurality of slidable adjustment slots 402B are positioned along respective sections of horizontal support bars 402, 402, 402A, as shown.

During manual set-up (as shown) or during an optional automated adjustment, a threaded drive shaft 404D threadably drives and engages a threaded drive bearing portion 404F of one of the horizontal support bars 402, 402, 402A and allows an operator to maintain a parallel position between respective horizontal support bars while adjusting laterally via sliding shafts 404A, 404A until a final bond-head position is achieved. While not shown, those of skill in the mechanical, electrical, and computer control arts, having studied the present discussion, shall recognize that threaded drive shaft 404D is supported by a driving motor, linear accelerator, or other motive means (all not shown) to allow horizontal motion as desired within the scope of the present invention, and that this motion and adjustment may be readily automated.

A threaded locking member 404E extends through respective slidable slots 402B and enables securing respective bonding heads 400A, 400B as desired relative to an inter-positioned layer 1 (FIG. 2) having respective defined bonding regions, either along an edges of a sheet, or as allowed by the present construction within the non-edge field of the sheet.

As will be noted in FIG. 1, the left-top side bond head sets 400A, 400B are slidably fixed to mounting block assemblies 450, 450. Mounting block assemblies 450, 450 are slidably adjustable along slots 402B, 402B and securable vial locking levers 404E, 404E in a manner similar to the independently mounted bonding assembly side of bonding station assembly 500. As shown, when mounting block assemblies 450, 450 are employed, respective bottom bonding assemblies' 400B in fixed, non-movable positions, although as will be recognized easy modification allows automated movement. Mounting block assemblies 450, 450 also include at a top or upper portion air cylinder unit members 401, 401 that extending air-cylinder arms fixed to top bonding heads 400A, 400A so as to allow relative vertical movement of respective top bonding heads 400A, as will be explained.

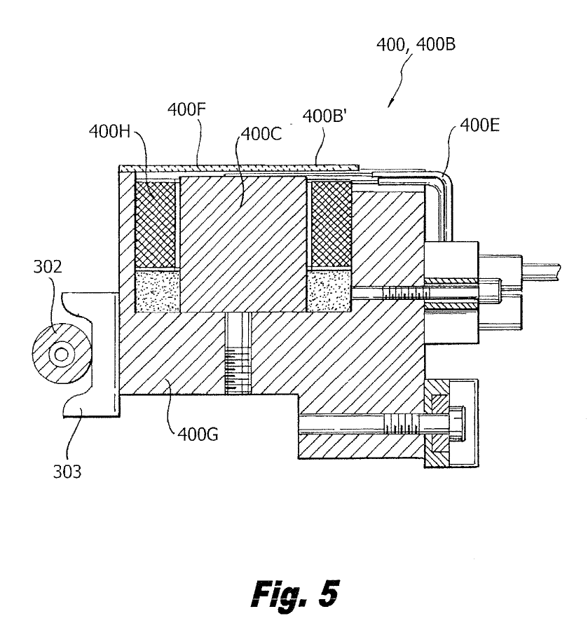

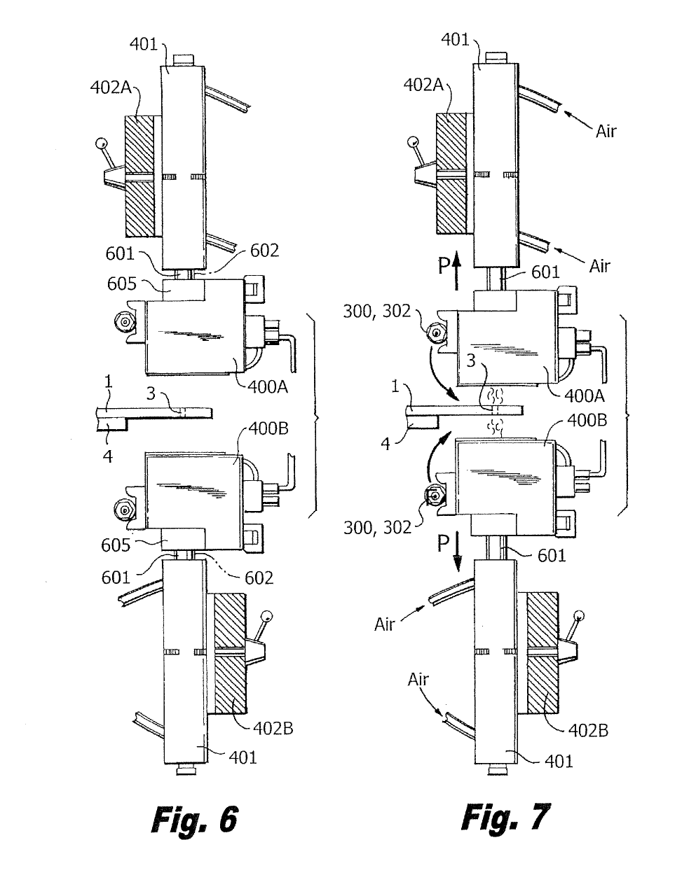

As will also be noted in FIG. 1 (and FIGS. 6 and 7), the right-bottom-side bond head sets 400A, 400B are slidably mounted to horizontal support bars 402, 402A via respective air cylinder unit members 401, 401 so as to allow vertical movement of each bond head 400A, 400B independent of each other during a use. As will be additionally appreciated, because respective bond heads 400A, 400B are operationally independent (each can create an induced field alone without mechanically joining or coupling to the other bond head portion as required in the related art), they may be split apart, and sheet members 1 may be slid between each bond head assembly 400A, 400B during stack assembly for enhanced positioning ease.

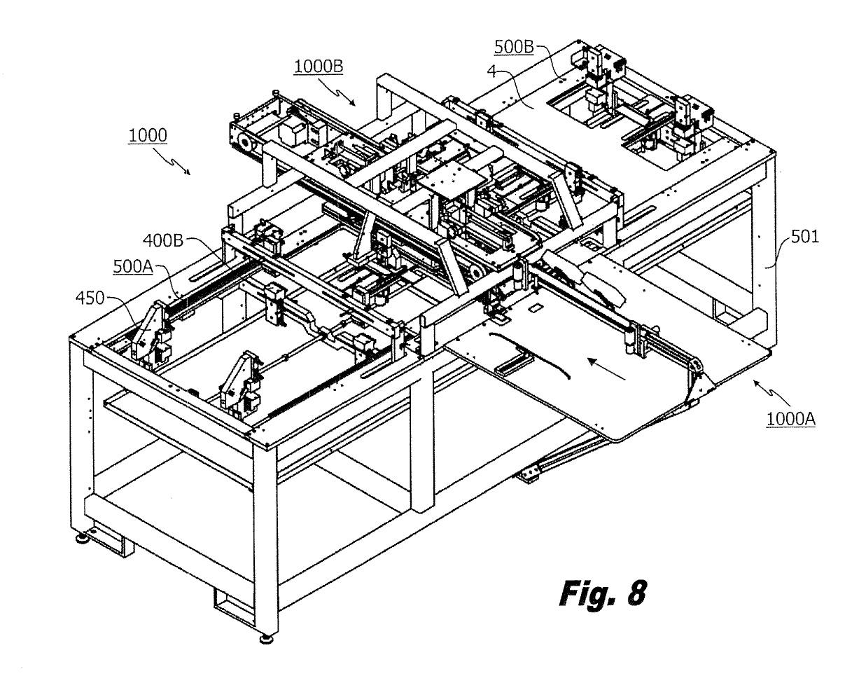

As a consequence, and as will be discussed in FIG. 8, the present construction supports the use of multiple bonding stations receiving fed sheet-lay-ups for eased and enhanced production rates.

As will also be appreciated from considering the present invention and FIG. 1, driving shaft 404D (with bearing 404F and the driving motor (not shown)) may readily position and reposition the horizontal support bars 402A, 402 along the entire field of sheet 1 by sliding along sliding shafts 404A, thereby allowing bonding within the greater field (between the edges) of the stack of respective sheets 1 to be bonded.

As will be appreciated, the present assembly in FIG. 1 is shown allowing for simple horizontal (left-right motion) along sliding shafts 404A (X-direction) and simple vertical (Y-direction) motion along slots 402B, whereby ready repositioning and adjustment is achievable. However, the present invention is not limited to this construction and it is specifically contemplated herein that linear accelerators, linear motors, drivers, and other automated accurate positioning devices (all not shown) may be joined to respective bond head assemblies 400A, 400B and respective air cylinder units 401 so as to move the same along respective support bars 402, 402A and sliding shafts 404A, 404A so as to be able to bond in any region of the entire field of stacked sheets 1, upon a computer control (not shown) or a mechanical control (shown via positioning locking pins 404E and other mechanisms allowing full X and Y direction movement relative to support plate 4.

As a consequence of the present construction and description, those of skill in the art will readily recognize that the present invention enables bonding to occur throughout the entire area of sheet 1. As a consequence, since at least one set of horizontal supports 402, 402A are split (not fixed to each other) they may move relative to a support plate 4 over the stack of sheets 1, may extend from one side or another, or may be independently supported allowing complete bonding motion.

As a consequence, it will be recognized following review of this description that the presently proposed solid copper pads 3 (FIGS. 2-2D) may be positioned anywhere within the sheet 1, commonly within target identifiers 2 (shown as a target ring for optical recognition), allowing for the use of and the secure fixing of sub-assembly stacks during lay-up (for example, a larger sheet (and stack of sheets) may be designed to contain a plurality of smaller integrated circuit designs that may be bonded close to their respective boarders within the larger sheet field for enhanced reliability and so as to prevent shifting during transport to later bonding stages.

Thus, while the presently preferred configuration employs a mix of split bonding head units and movement systems, alternative combinations and configurations may be provided without departing from the scope of the present disclosure and will allowing for motion of the bonding heads in three directions (X, Y, and Z), as well as the use of individual or singular bonding head (single side bonding) assemblies.

Referring now specifically to FIGS. 2, 2A, 2B, 2C, and 2D, the present discussion notes the use of differently shaped solid copper pads 3, 3A, 3B, 3C, and 3D, or optionally a series of concentric rings 3A′, 3A″ and a copper pad 3A centered therein. It is noted that each copper pad shown is continuous in its central region but the shapes are not limited to the ones shown, and may be employed as any regular or irregular copper pad. The copper pad acts as an improved heat source during induction on every layer and provides a unified and homogenous bonding thermal (heat) supply region to improve bonding reliability through multiple stack layers. The concentric rings 3A′, 3A″ do not generate heat (typically they are too far from the thermal concentration although they will induct/heat if sufficiently close), they act as constraints (dams) for the bonding resin that will flow during bonding and then cure in place. Thus, the concentric rings are not in short circuit, they do not connect to each other or the central copper pad, but they do provide an improved quality of bonding by containing resin during bonding and improving quality control.

Pad types, sizes and dimensions can vary according to the customer's border area design, or to the available area on the inner layers within a multiplayer construct. For example, a copper pad may be shaped as a large “L” allowing for easy corner bonding of a sub-assembly within a larger sheet. Alternatively, a copper pad member may extend in some way beyond the normal diameter of the center of the bonding head, and employing the present invention it is contemplated that the bonding heads may be driven along the copper pad member according to a desired bonding rate to secure the entire bonding pad area. The customer can also choose to etch the concentric rings if space allows so that the etchings will similarly serve as a resin dam mechanism to contain the melting/fluid resin during bonding.

Specifically referring now to FIG. 2, bond head mounting block 450 is slidably positioned along a slid-adjustment direction S relative to adjustment slot 402B on horizontal support rail or bar 402, as shown. A terminal mounting block 200 is fixed to block 450 and receives electrical power and thermal couple wires serving to bonding head assembly 400A, as will be discussed. Top bonding head assembly 400A is positioned to a movable plate 605 joined with extending air cylinders (shown later) extending from air cylinder unit 401 supplied with controlled air supply 401A via a plurality of hoses and joints as shown. As a consequence of this construction, it will be recognized that top bonding head assembly is readily movable in the vertical position P relative to support plate 4, sheet 1 (or a stack of sheets 1) positioned between respective bonding heads, and bottom bonding head 400B.

Bottom bonding head assembly 400B is shown fixably mounted to a bottom portion of mounting block 450, and is covered with a cover plate member 400B′ as will be discussed in further detail. For example, cover plate member 400B′ may be a ceramic (here alumina, SiO2, Zircon, etc.), a metal, a fiberglass, a polymeric material, or a multiple layer construction that is sufficient to resist thermal degradation eliminate adhesion from spilled resin during use and deformation under pressure. For example, this construction keeps any resin that may flow out of the bonding area of the panel from adhering to the coil and ferrite core. Here the alumina is a very hard non-stick surface; so that any resin that flows onto it will be easily removed with a razor blade type scraper after cooling.

Included on each respective top and bottom bonding head assembly 400A, 400B is a cooling system 300, shown here as an air cooling system with an air supply feed 301, but nothing herein shall so limit the disclosure. For example, cooling system 300 may include radiant cooling fins extending from each head assembly, internal liquid or air-cooling systems, and multiple-location cooling systems. It shall be recognized that cooling system 300 aids and speeds thermal cycling by providing a cooling effect to both respective bond head assemblies, but also optionally to respective bonded sheets, and bonding sites, etc. Thus, cooling systems 300 improve rapid cycle time, reduce required time-between-bondings and improves quality by rapidly cooling the bonding site during sheet with drawl from the bonding position and movement between positions.

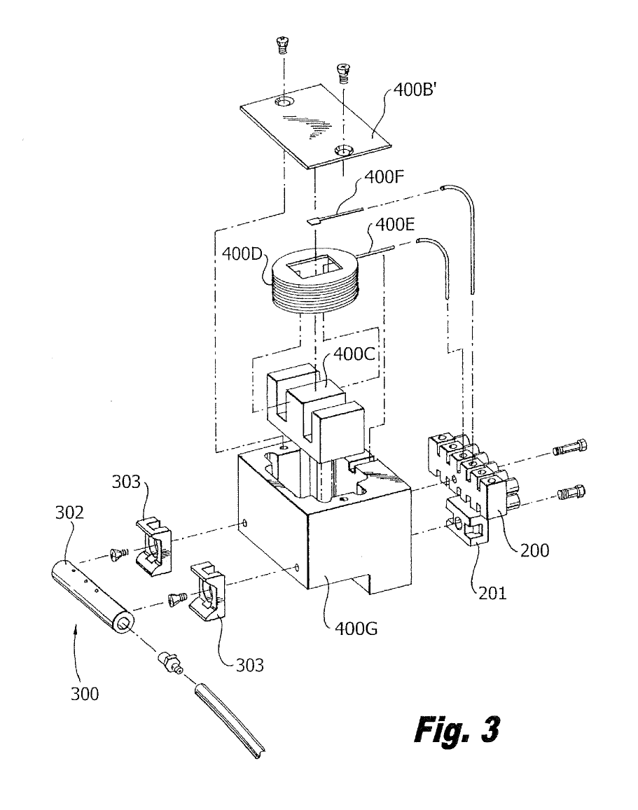

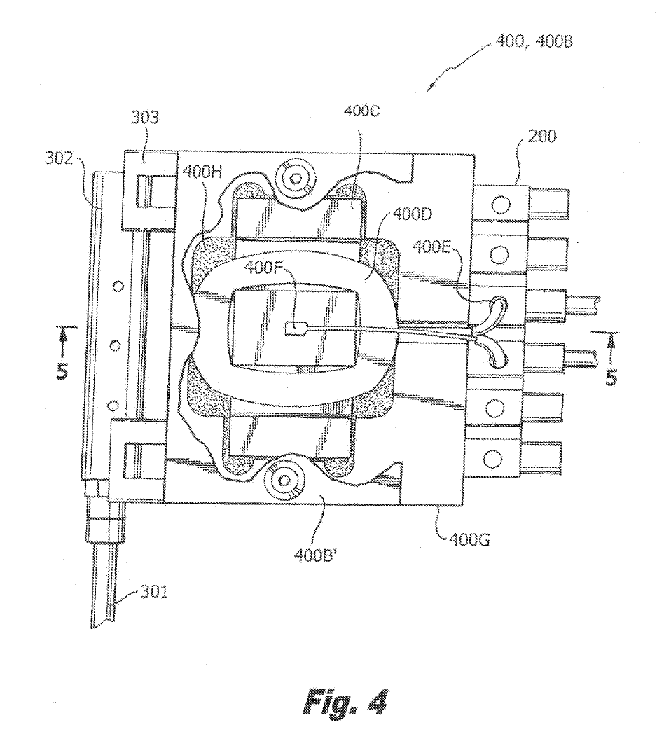

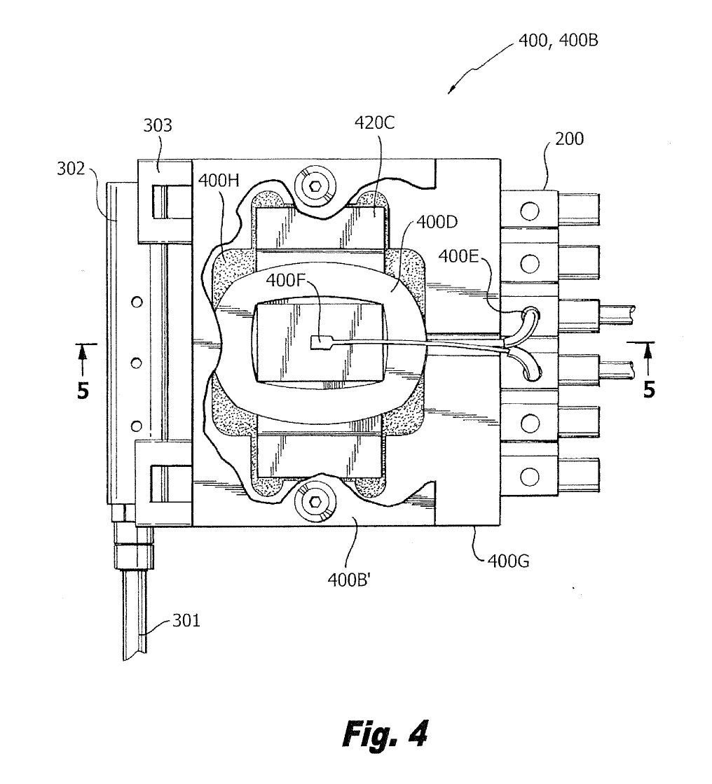

Referring now to FIGS. 3, 4, and 5, a bonding head assembly 400 is shown, here oriented as a bottom bonding head assembly 400B, although both top and bottom assemblies are similarly constructed (terminal block members 200 are differently positioned as noted in the figures). A core block member 400G is formed as a generally rectilear body and includes an inner cavity having a flat bottom for receiving an E-shaped or 3-legged ferrite core element 400C and a wound core 400D having an extending core power supply 400E for supply electrical current. A thermocouple 400F, is formed having a reasonably thin film or foil member at its end so as to lie flat on the top of the central leg of the E of the ferrite core 400C and allow cover late 400B to be positioned to cover the entire assembly in a flat manner. Since thermal couple 400F is so thin (no more than 1/16^{th} of an inch), there is no detriment or stress concentration on the center of the E of the ferrite core so that maximum assembly temperature is accurate (central location of the thermal couple for improved temperature reliability) and simple (a simple positioning is required), and simple replacement is enables by merely removing cover plate 400B′. After such assembly, a bonding epoxy 400H (commonly thermal carbon black) is used to fill in any remaining voids and lock the assembled ferrite core and core into core block 400G. It will be recognized that different bonding epoxy compositions may be used to fill and secure the assembly without departing from the scope and spirit of the present invention.

Respective thermal couple lead wires and power supply wires to the wound core are joined to terminal block 200 secured to mounting core block 400G by a mounting bracket 201 (in block 400B) or on a mounting block 450 side for top bond head assembly 400A (see FIG. 2). Cooling mount brackets 303 secure cooling system 300 in position and allow for the easy direction of cooling air at the hot bond head and the bonded sheet stack for reduced cycle time.

As will be appreciated by those of skill in the art having read and understood the present disclosure, due to the shape of E-ferrite cores the center-leg of the E serves to both concentrate the induced field for enhanced bonding and to provide strong central support for the bonding stack during the bonding step. As a consequence, while thermal couple 400F is preferably positioned (as shown) as close to the center of the induced field leg as possible, alternative thermal couple positions may be employed without departing from the scope and spirit of the present invention. For example, a thermal couple may be placed near the top of core 400D between the legs of the E-ferrite core for assembly convenience. As noted, the proposed system has an imbedded thermocouple probe that measures the temperature of the coil, thus allowing for a predictable curve of for a controlling temperature ramp rate and voltage supply. It will be similarly recognized that alternatively dimensioned E-shaped ferrite cores may be employed without departing from the scope of the present invention.

In practice, cooling system 300 may be (a) continuously activated, (b) activated upon reaching a temperature set point (determined by a locally set thermal couple on/in the bond head or proximate to the bond head or stack of sheets 1), or (c) preferably activated after the heat temp/bond cycle has completed and works sufficiently quickly to accomplish cooling between cycles by supplying clean filtered air for temperature maintenance.

As also suggested the present system provides for a computer control mechanism enables individual control of a heating ramp rate, hold time and cooling time and power supply as will be discussed.

As will also be recognized by those of skill in the art having view the entire disclosure, the use of E-shaped cores enables the use of 100% of the magnetic field for each head during bonding, with approximately 50% of the induced field cycling through each outer side of the “E” and returning to the thicker central “E” portion, and with 100% of the field centered in the bonding head contact surface. As a consequence, the present invention provides at least twice (2×) the width of a conventional induction coupling area than that available in the related art noted above. As an additional benefit, where two inductive heads are used in vertical cooperation the magnetic fields from each E-core join forming a very wide inductive field and need only extend a portion of the way through a sheet stack (although complete penetration and some field overlap is preferably achieved to secure bonding rapidly).

It is noted that the present system, includes the use of a high-temperature resin or epoxy 400G within a holder element 400G to secure the core and winding elements in a preferred embodiment but the use of resin or epoxy 400G is not required for operation and serves only to improve reliability and ease of use.

During operation, the present system with use of a ceramic cover plate 400B′ (or a high temperature metal or a high temperature polymeric plate cover) enable the use of substantially high temperatures prior to functional break-down. While conventional bonding temperature ranges are from approximately 250-375° F. or 380° F. depending upon the bonding systems used, the present system enables the use of temperatures as high as 900-1000° C. before final functional break down. As a consequence, the present system speeds inductive thermal bonding across the range of likely bonding temperatures desired by customers.

As noted above, the use of a continuous cooper pad further aids rapid thermal transfer to bond in a practice contradicted by the teachings of the related art. As a consequence, the copper pad center experiences the temperature as closely as possible to a true induced temperature proximate the cover plate 400B′ as measured by thermocouple 400F allowing for reliable thermal bonding control.

As a consequence, the present construction enables heat up rates to inductive bonding from approximately 10 seconds to 1 minute, depending upon a user desire. This is in complete contrast to the related art thermal cycle systems that operate on the order of multiple minutes to induce sufficient thermal bonding penetration for heating related lay-ups or stacks.

Referring now to FIGS. 6 and 7 it will be appreciated that respective top and bottom bond head assemblies 400A, 400B are positioned fixed to respective air cylinder end members 605 which are, in turn, joined to ends of operative air cylinders 601, 602 for each respective air cylinder unit 401, 401 for each bonding group. During operation and initial positioning, air cylinders 601, 602 are fully retracted (FIG. 6) and cooling system 300 containing cooling manifold 302 is not employed. Although it is recognized that cooling system 300 may be employed at any time or continuously throughout the bonding cycle. Following the initial bonding step, as respective bond heads 400 separate from the now-bonded lay-up, it is presently preferred that cooling systems 300 operate directly, allowing cooling to the as-bonded lay-up and to each bond head 400. It will also be appreciated, that while FIGS. 6 and 7 depict the use of dual-bonding head movement (dual use of air cylinder units 401, this is not required and only one bond head may be optionally movable (the other unit remaining fixed).

As a result of the present construction, it will be recognized that cooling system 300 may be employed at multiple times during the bonding cycle depending upon a consumers need. Additionally, cooling system 300 may be provided with multiple and differently-positioned cooling heads or cooling nozzles extending to cool multiple locations or to focus cooling in a preferred location during rapid cycling. Therefore, it is proposed that those of skill in the art, having appreciated the present disclosure, will recognize that the proposed bond head assembly and cooling system is readily adapted to diverse consumer needs while continuously providing improved reliability and cycle time.

Referring now to FIG. 8, it shall be recognized that the presently proposed bond head systems and assemblies may be employed in complex unified bonding systems 1000, containing individual loading stations 1000A and aligning stations 100B, and multiple bonding stations 500A, 500B, as shown. During use, system 1000 may readily load, align, and begin bonding at a first station 500A, and then during bonding at station 500A, load, align and begin bonding at the second station 500B. A third or additional stations may be provided without departing from the scope and spirit of the present invention. Consequently, it will be appreciated by those of skill in the art, having reviewed the entire disclosure herein, that the present invention enables the use of multiple-bonding station systems for speedy processing.

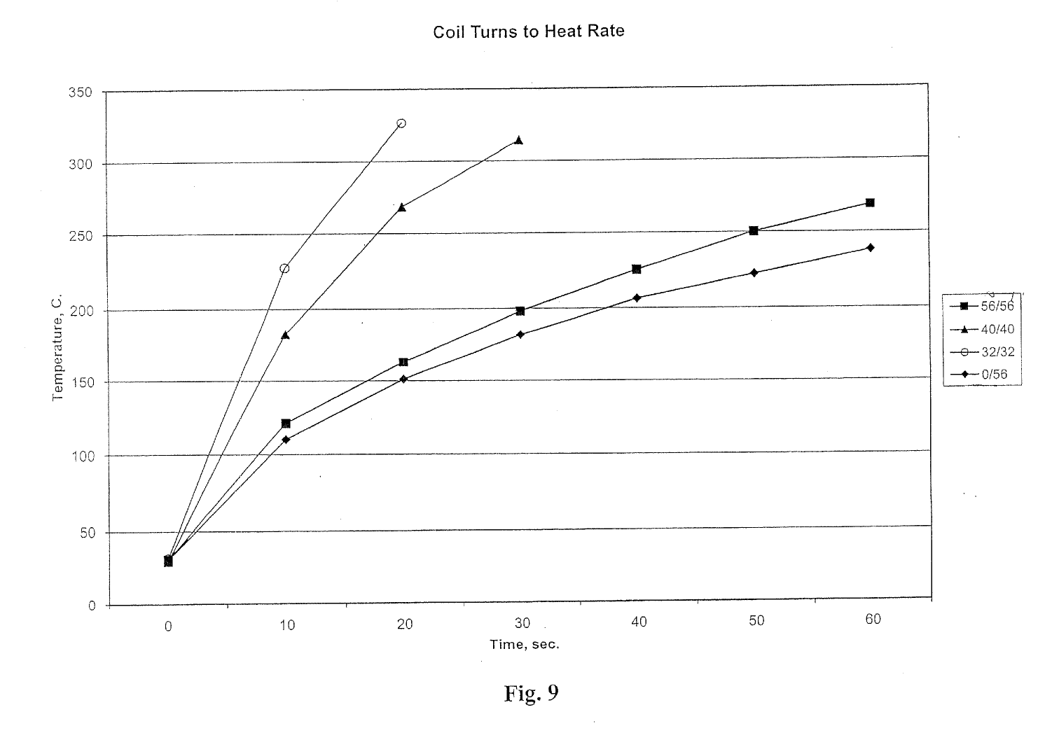

Referring now to FIG. 9, it has been recognized by the applicant that due to the present construction (providing improved thermal capability), the risk of over or too-rapid heating may occur under non-programmed or un-controlled circumstances. This risk is balanced by the desire to have a very rapid heat up to speed cycle time and the need to avoid damage to the equipment and the bonded stack of sheets 1.

Consequently, it has been recognized that while core 400D may comprise any number of windings to function, a preferred range of function is achievable by selecting a preferable number of windings or turns. As noted below in Table 1, a listing of number of turns in coil 400D is presented with the respective measured induced inductances, and the standard deviation range relative to conventional measurements. In Table 1, a bond head assembly such as bond head assembly 400B as detailed in FIG. 1 is provided absent epoxy or resin 400H so as to allow simple interchange of cores 400D with different numbers of windings. It will be recognized that the number of windings recognized herein may be adaptable based upon the gauge of wire employed in the coil and the quality of the metal therein.

TABLE 1

| Turns | Inductance |
|---|---|
| 56 turns | 347-360 uH (355 +/− 8 Uh) |
| 40 turns | 195-205 uH (200 +/− 5 uH) |
| 32 turns | 139-146 uH (142 +/− 3.6 Uh) |

An additional experiment, or series of experiments, was conducted using sets of similarly arranged bond heads 400, in opposing positions similar to those noted in FIG. 2, with a separation or gap of approximately 0.30 inches (+/−0.20 inches) so as to simulate measurable inductances and heating rates when only one or both bonding heads with differing windings and stack heights were employed. A thermocouple similar to 400F was employed between the spaced bonding heads as well as within each bonding head 400, and an inductance measuring device was employed to track the inductance generated (noting similarity to the results in Table 1). The results of the experiments are summarized in Table 2.

TABLE 2

| Turns for top/ | 0 | 10 | 20 | 30 | 40 | 50 | 60 |
|---|---|---|---|---|---|---|---|
| bottom head | Sec. | Sec. | Sec. | Sec. | Sec. | Sec. | Sec. |
| 56/56 | 31 | 121 | 163 | 198 | 225 | 250 | 268 |
| 40/40 | 30 | 183 | 268 | 314 | stopped | | |
| 32/32 | 32 | 227 | 326 | stopped | | | |
| 0/56 | 31 | 110 | 151 | 182 | 206 | 222 | 238 |

As is noted, due to the very rapid temperature gradient for the 40/40 and 32/32 turn cores the experiment was stopped to preserve the testing equipment. The graphical plot of Table 2 is noted in FIG. 9.

A number of items will be appreciated from FIG. 9. The first item of impact, is that the heating rate of the sole bond head (the 0 turns/56 turns circumstance for respective top and bottom heads) provides a heating rate the same as or nearly the same as that of the 56/56 turn case. Consequently, it is appreciated that the use of independent bond head assemblies (a single bond head) is a viable option and may be substantially effective for use in bonding practice without adaptation, and can be used independently of an opposing bonding head (top or bottom). This construction also substantially expands the freedom for bonding use within a sheet field or in alternative bonding systems according to a customer's needs. This ability to bond freely within the sheet field will allow the expansion of bonding applications and bonding-design freedom applications within the industry.

The second item recognized, is that for the present construction a pairing of the 32 turns/32 turns core bonding heat system provides optimal heating ramp rates so as to stay within the general operational temperature range (noted above) for the bonding resins employed by the industry (from approximately 10 seconds to one minute—much faster than the related art bonding times of multiple minutes). Thus, the present construction enables the use of rapid but controllable bonding and reduced bonding cycle times.

As a particular advantage, employing the unique features of thermal tailoring wherein the thin-film thermocouple construction 400F is employed directly above the central E- of the ferrite core, and similar parallel tracking thin thermal couples may be placed between respective cooper pads 3 and/or between respective cover layers 1 and monitored during thermal bonding, the tracking of the ramp and bonding rate, and thermal penetration of stacked layers 1 is readily achieved. Thus, the use of the present system allows users to employ either a single bond head or multiple bond heads, in multiple or movable positions, to achieve a controllable a thermal spectrum throughout a multiplayer thickness and ultimately improve bonding cycle efficiency.

As another alternative embodiment of the present invention, the bonding head systems noted herein may be optionally attached with cognizable minimal modification to the controllable motion systems as noted in Applicant's co-pending related applications U.S. Ser. No. 60/783,888 filed Mar. 20, 2006, now PCT/US07/64435 filed Mar. 20, 2007 (pending), the entire contents of which are herein incorporated by reference. Thus it is appreciated that the present system is readily managed to determine an optimum ramp rate (voltage/temperature) that is readily record-able in operational software and hence reliably repeatable in production environments.

In the claims, means- or step-plus-function clauses are intended to cover the structures described or suggested herein as performing the recited function and not only structural equivalents but also equivalent structures. Thus, for example, although a nail, a screw, and a bolt may not be structural equivalents in that a nail relies on friction between a wooden part and a cylindrical surface, a screw's helical surface positively engages the wooden part, and a bolt's head and nut compress opposite sides of a wooden part, in the environment of fastening wooden parts, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims.

What is claimed is:

1. An inductive bonding system, comprising:
a controllable motion system for operating said inductive bonding system;
at least one inductive bonding head member, said inductive head member further comprising:
an E-shaped ferrite core member having a central leg and two outer legs joined by a back member;
at least a first coil member bounding said central leg and having a plurality of coil turns;
a cover plate member on a contact surface of at least said central leg of said E-shaped ferrite core member and having a bonding surface opposite said contact surface during a use of said bonding system;
at least one rigid core block means for bounding said E-shaped ferrite core member and said first coil member, and for supporting said cover plate member; and
a temperature measurement means between said cover plate member and said E-shaped ferrite core member, whereby said ferrite core member and said coil member generate an inductive field during said use that is substantially split between said central leg and said two outer legs enabling a concentration of said field proximate said central leg for improved inductive bonding.

2. An inductive bonding system, according to claim 1, wherein:
said cover plate member includes a material selected from a material group comprising:
of at least one of a ceramic material, a metallic material, a polymeric material, and a combination of two of said ceramic, metallic, and said polymeric materials.

3. An inductive bonding system, according to claim 1, further comprising:
control means for positioning and electrically controlling said inductive bonding head member relative to an inductive work position, whereby during said use said control means for positioning enables said inductive bonding head member to approach and retract from said work position.

4. An inductive bonding system, according to claim 1, further comprising:
cooling means for providing a cooling management of one of said inductive bonding head member during said use and an external bonded material during said use, wherein said cooling means enables a reduced bonding cycle time.

5. An inductive bonding system, according to claim 1, further comprising:
control means for aligning and positioning said inductive bonding head member relative to said inductive bonding at a work position during said use.

6. An inductive bonding system, according to claim 1, wherein:
said plurality of coil turns in said at least first coil member is between 30 and 56 turns.

7. An inductive bonding system, according to claim 6, wherein:
said plurality of coil turns in said at least first coil member is between 30 and 40 turns.

8. An inductive bonding system, according to claim 1, further comprising:
at least a second inductive bonding head member, said second inductive bonding head member further comprising:
a second E-shaped ferrite core member having a central leg and two outer legs joined by a back member;
a second coil member;
a second cover plate member on said central leg of said second E-shaped ferrite core member;
a second rigid core block means for bounding said second E-shaped ferrite core member and said second coil member, and for supporting said second cover plate member; and
a second temperature measurement means between said second cover plate member and said second E-shaped ferrite core member.

9. An inductive bonding system, comprising:
at least one inductive bonding head member, said inductive head member further comprising:
an E-shaped ferrite core member having a central leg and two outer legs joined by a back member;
a coil member bounding said central leg and having a plurality of coil turns;
a cover plate member on said E-shaped ferrite core member and having a bonding surface opposite said E-shaped ferrite core member during a use of said bonding system;
a core block means for bounding said E-shaped ferrite core member and said first coil member, and for supporting said cover plate member during said use; and
a temperature measurement means between said cover plate member and said E-shaped ferrite core member, whereby said ferrite core member and said coil member generate an inductive field during said use that is substantially split between said central leg and said two outer legs enabling a concentration of said field proximate said central leg for improved inductive bonding.

10. An inductive bonding system, according to claim 9, further comprising:
adjustment means for positioning and for securing said inductive bonding head member relative to a desired inductive work position throughout a field of possible work positions, whereby during said use said adjustment means for positioning and for securing enables said inductive bonding head member to repositionably approach a work position for bonding and to be re-locatably secured with a field of possible work positions for enhanced bonding efficiency.

11. An inductive bonding system, according to claim 9, further comprising:
cooling means for providing a cooling management of one of said inductive bonding head member during said use and an external bonded material bonded during said use, wherein said cooling means enables a reduced thermal cycle time.

12. An inductive bonding system, according to claim 9, further comprising:
computer controlled means for repositionably aligning and operating said inductive bonding head member relative to a desired inductive work position throughout a field of possible work positions during said use.

13. An inductive bonding system, according to claim 9, wherein:
said plurality of coil turns in said at least first coil member is between 30 and 56 turns.

14. An inductive bonding system, according to claim 13, wherein:
said plurality of coil turns in said at least first coil member is between 30 and 40 turns.

15. An inductive bonding system, comprising:
at least a first inductive bonding head member;
at least a first multi-layer circuit construction stack comprising at least one layer of bonding resin between two printed circuit layers;
each said printed circuit layer including an inductive bonding work region positionable relative to said bonding head member; and
each said inductive bonding work region comprising:
one of a continuous metallic region, a discontinuous metallic region, an assembly of a ring member bounding a centrally located continuous metallic region, whereby during a bonding said inductive bonding head member induces a thermal field relative to said entire bonding work region, liquefies said proximate bonding resin, and bonds said respective printed circuit layers.

16. An inductive bonding system, according to claim 15, wherein:
said inductive bonding work region includes said continuous metallic region; and
said continuous metallic region is a Copper (Cu) metallic region.

17. An inductive bonding system, according to claim 16, wherein:
said continuous metallic region is bounded by a ring member; and
said ring member is constructed from one of a Copper (Cu) ring and an etched region in said printed circuit layer.

18. A printed circuit layer, comprising:
at least one printed circuit layer sheet having an inductive bonding work region defined within the edges thereof; and
each said inductive bonding work region comprising:
one of a continuous metallic region, a discontinuous metallic region, an assembly of a ring member bounding a centrally located continuous metallic region, whereby during a bonding said inductive bonding head member induces a thermal field relative to said entire bonding work region, liquefies said proximate bonding resin, and bonds said respective printed circuit layers.

19. An adjustable inductive bonding system, comprising:
at least first and second inductive bonding head members, each said inductive head member further comprising:
an E-shaped ferrite core member having a central leg and two outer legs joined by a back member;
a coil member bounding said central leg and having a plurality of coil turns;
a cover plate member on said E-shaped ferrite core member and having a bonding surface opposite said E-shaped ferrite core member during a use of said bonding system;
a core block means for bounding said E-shaped ferrite core member and said first coil member, and for supporting said cover plate member during said use;
a temperature measurement means between said cover plate member and said E-shaped ferrite core member, whereby said ferrite core member and said coil member generate an inductive field during said use that is substantially split between said central leg and said two outer legs enabling a concentration of said field proximate said central leg for improved inductive bonding;
means for independently positioning said first and said second bonding head members and for repositionably moving said first and second bonding head members toward each other during said use;
cooling means on at least one of said inductive bonding head members for providing a cooling management of at least one of said one inductive bonding head member during and an external bonded material bonded during said use, wherein said cooling means enables a reduced thermal cycle time of said inductive bonding system.

20. An adjustable inductive bonding system, according to claim 19, wherein:
said means for independently positioning and for repositionably moving further comprises:
means for securely positioning said first and second inductive bonding head members at a desired inductive work position throughout a field of possible work positions in said system;
said means for securely positioning, comprising:
at least a first support bar member;
at least one of said inductive bonding head members on said support bar member;
a means for sliding ones of said inductive bonding head members relative to said at least first support bar member to a desired said inductive work position, whereby said means for sliding enables easy repositioning of said ones of said inductive bonding head members.
